(19) United States
(12) Patent Application Publication
(10) Pub. No.: US 2026/0314809 A1
(43) Pub. Date: Oct. 15, 2026

(54) WAFER CLEANING BRUSH WITH NODULE-TIP FLUID DELIVERY

(71) Applicant: TCNV, LLC, Minden, NV (US)

(72) Inventors: Briant Benson, Placerville, CA (US); Michael Dobbins, Citrus Heights, CA (US); Maxim Nesmiyan, Antelope, CA (US); David Ottman, Carmichael, CA (US); William Shortridge, Fair Oaks, CA (US)

(21) Appl. No.: 19/544,297

(22) Filed: Feb. 19, 2026

Related U.S. Application Data
(60) Provisional application No. 63/786,250, filed on Apr. 9, 2025.

(51) Int. Cl. A46B 13/04; A46B 13/00; A46D 1/00; H10P 72/00; H10P 70/00

(52) U.S. Cl. CPC A46B 13/04; A46B 13/001; A46D 1/0207; H10P 72/0412; A46B 2200/3073; H10P 70/20

(57) ABSTRACT

A wafer-cleaning brush includes a hollow core configured to receive a cleaning fluid and a plurality of fluid-permeable nodules disposed on the core. Each nodule includes a dispensing outlet at a distal tip in fluid communication with the core such that the cleaning fluid is dispensed at or near a brush–wafer interface during cleaning. In embodiments, the dispensing outlet comprises a pore at the distal tip and/or a passive slit-based outlet configured to regulate discharge of the cleaning fluid. Distal tips may include surface features that guide fluid laterally across a wafer surface. A cleaning system may combine deionized water and chemistry upstream of the brush, optionally monitor dissolved oxygen, and deliver fluid to a wet module for cleaning and subsequent drying.

### PRIORITY INFORMATION

The present application claims priority to United States Provisional Patent Application No. 63/786,250, filed Apr. 9, 2025, the contents of which are incorporated herein as if set out in full.

### TECHNICAL FIELD OF THE DISCLOSURE

The present disclosure relates to wet processing of substrates and, more particularly, to wafer-cleaning brushes and cleaning systems used in post-chemical mechanical planarization (post-CMP) and other semiconductor substrate cleaning operations. Embodiments described herein relate to brushes configured to dispense one or more cleaning fluids through an array of brush nodules at a brush–wafer interface.

### BACKGROUND AND DESCRIPTION OF THE RELATED ART

Semiconductor manufacturing commonly includes wet cleaning operations for removing particles, residues, and process byproducts from wafer surfaces. In many tool architectures, a rotating or translating brush contacts a wafer while one or more process fluids are supplied to the cleaning region. Process fluids may include deionized (DI) water, one or more chemical cleaning agents, or mixtures thereof, depending on the cleaning objective and the process integration.

In some systems, process fluids are delivered to the cleaning region using externally mounted spray bars, nozzles, or similar hardware positioned near the brush–wafer interface. While external spray delivery can provide high flow rates and rapid refresh of fluid at the interface, it can also create overspray, runoff, and non-uniform fluid coverage, particularly in confined wet modules. External spray delivery may also increase fluid consumption and may contribute to aerosolization or unintended wetting of surrounding hardware, which can increase maintenance burden.

Certain external delivery configurations can also promote formation of a continuous fluid film at the brush–wafer interface. Under some operating conditions, such a film may reduce effective mechanical contact between brush nodules and the wafer, which may decrease cleaning performance and/or increase process variability. In addition, externally applied chemistry streams can be sensitive to nozzle or spray-bar condition (e.g., clogging, drift, and alignment), which can affect repeatability over time.

Separately, some brush architectures deliver DI water or other fluids through a brush core and into a porous brush body. However, there can remain a need for improved, distributed placement of fluid at or near the distal tips of nodules where contact and scrubbing occur, while also reducing reliance on external spray infrastructure. There can further remain a need for architectures that support controlled delivery of multiple fluids (e.g., DI water and chemistry), reduced dripping when idle, and improved uniformity of wetting at the brush–wafer interface.

The present disclosure provides wafer-cleaning brushes and related systems for post-chemical mechanical planarization (post-CMP) and other precision wet cleaning processes.

### SUMMARY OF THE DISCLOSURE

The present disclosure relates to wafer-cleaning brushes used in post-chemical mechanical planarization (post-CMP) and other precision wet cleaning processes. The disclosed brush architecture integrates cleaning-fluid delivery through an array of cleaning nodules such that deionized (DI) water, chemical cleaning agents, or mixtures thereof are delivered and dispensed at or near a brush–wafer interface, optionally without reliance on external spray.

In one aspect, a wafer-cleaning brush includes a hollow cylindrical core having a proximal end defining a fluid inlet and a distal end that is sealed to form an internal fluid chamber and to promote longitudinal flow of cleaning fluid along a length of the core. The inlet end may be coupled to an inlet interface that inhibits leakage when installed. A plurality of nodules are affixed to an exterior surface of the core and extend radially outward from the core. Each nodule is formed of a fluid-permeable material, such as polyvinyl alcohol (PVA), and includes a distal tip configured to contact a wafer during operation.

Each nodule includes a dispensing outlet at the distal tip in fluid communication with the internal fluid chamber such that cleaning fluid introduced into the core is distributed to the nodules and dispensed at the distal tips during wafer cleaning. By dispensing cleaning fluid at the distal tips, the brush provides localized, distributed delivery of DI water and/or chemistry directly at the point of mechanical engagement between the brush and the wafer, thereby improving coverage uniformity and reducing overspray and runoff associated with external spray systems.

Dispensing outlet embodiments: In certain implementations of the invention, the dispensing outlet comprises a pore or aperture formed at or near the distal tip of the nodule. The pore may be circular, slit-shaped, elliptical, or otherwise shaped to regulate flow while maintaining mechanical integrity. In one non-limiting example, a pore has an effective diameter of about 0.1 mm to about 2.0 mm and may be formed during molding or by post-processing such as laser drilling or punching.

In other implementations, the dispensing outlet comprises a passive valve positioned at or near the distal tip of the nodule to regulate release of cleaning fluid. The passive valve may be configured to remain substantially closed under zero or low internal pressure and to open in response to internal pressure during active cleaning. A non-limiting example of a passive valve is a duckbill-style slit valve having flexible flaps and a narrow slit or X-shaped opening. In one example, the passive valve is configured to open upon reaching a pressure threshold of about 1 psi to about 5 psi, and to return toward a closed state when pressure falls below the threshold. In one example, the passive valve comprises a tapered internal chamber configured to direct the cleaning fluid toward a valve seat.

The passive valve may include one or more features selected from stiffening ribs, anti-reflux structures, and micro-mesh pre-filters to reduce backflow, clogging, or particle ingress. Valve actuation thresholds may be tuned by adjusting a thickness, durometer, and/or geometry of valve flaps, and advanced versions may incorporate multi-layer valves, venturi structures, and/or directional bias.

In certain embodiments, a dispensing outlet includes a lumen extending within the nodule and a slit at the distal tip, where the slit is configured to open in response to internal fluid pressure and/or deformation of the nodule during contact with the wafer. For example, the lumen may be formed during molding and the slit may be created by post-processing. The slit may be oriented substantially parallel to a rotational direction of the brush to promote repeatable opening and controlled release.

Distal-tip surface features: A distal tip of a nodule may include surface features selected from ridges, grooves, channels, microchannels, textures, and patterned arrays. The surface features may be arranged, for example, in radial, axial, spiral or helical, chevron, or crosshatch patterns. Such surface features may function as microfluidic guides that direct cleaning fluid laterally across the wafer surface, disrupt boundary-layer flow, and reduce fluid pooling or stacking that can lead to hydroplaning, while maintaining effective scrubbing contact.

In another aspect, a wafer-cleaning system includes the wafer-cleaning brush described herein, a fluid supply coupled to the fluid inlet of the core, and a drive configured to rotate the brush during cleaning. In some embodiments, DI water and one or more chemical agents are combined upstream of the brush core, for example via a Y-fitting. In some examples, a dissolved-oxygen (DO) meter or similar in-line monitor is positioned upstream of the Y-fitting to assess saturation levels.

In some alternative embodiments of the invention, external spray bars are omitted such that cleaning fluid is delivered to the wafer solely through the brush core and the nodules. This configuration reduces overspray, simplifies tool architecture, and enables on-demand chemistry placement at the brush-wafer interface.

In certain embodiments, the core includes a plurality of distribution ports disposed along the length of the core to deliver cleaning fluid from the internal chamber into the fluid-permeable material of the nodules, and at least one of a port size, port count, and port distribution pattern is selected to equalize cleaning-fluid delivery along the brush length.

In some embodiments, the core 110 is implemented as or includes one or more removable rail modules or segments (see, e.g., FIGS. 5–8) that each support a subset of the nodules. Such rail modules can be configured as replaceable consumable components, allowing replacement of rail modules without replacement of an entire brush assembly, while maintaining tool-side interfaces defined by the cleaning tool.

In use, the system may be operated in a method for cleaning a wafer that includes introducing a cleaning fluid into the proximal end of a hollow cylindrical brush core having a sealed distal end; rotating the brush while maintaining contact between distal tips of the nodules and a wafer surface; and dispensing the cleaning fluid from dispensing outlets at the distal tips of the nodules onto the wafer surface during rotation. The cleaning fluid is thereby applied precisely at the brush-wafer interface, optionally without use of external spray bars.

The foregoing aspects and embodiments may be implemented individually or in combination. Variations and modifications will be apparent to those skilled in the art in view of the present disclosure.

These and other advantages and features of the present invention are described with specificity so as to make the present invention understandable to one of ordinary skill in the art.

### BRIEF DESCRIPTION OF THE DRAWINGS

Elements in the figures have not necessarily been drawn to scale in order to enhance their clarity and improve understanding of these various elements and embodiments of the invention. Furthermore, elements that are known to be common and well understood to those in the industry are not depicted in order to provide a clear view of the various embodiments of the invention. Thus, the drawings are generalized in form in the interest of clarity and conciseness.

FIGS. 1A and 1B illustrate a representative nodule (130) having a distal tip (132) with surface features (134) and a pore or aperture (136).

FIG. 2 is a perspective view of a cylindrical wafer-cleaning brush assembly (100) including a core (110) carrying a plurality of nodules (130) and including an end hub/cap (120) having a drive coupling feature (122) and a central bore/opening (124).

FIGS. 3A–3C illustrate a representative nodule (130) with a slit opening (142) at the distal tip (132), including a closed state (FIG. 3A), an open state (FIG. 3B), and a cross-sectional view (FIG. 3C) illustrating an internal passage/lumen (146) leading toward the slit opening (142).

FIG. 4 is a schematic diagram of a wafer cleaning system (200) in which a deionized water stream (212) and a chemistry stream (214) are combined at a mixer (216), optionally monitored by one or more dissolved oxygen meters (218a, 218b), and delivered to a wet zone/module (230) for cleaning of a wafer (150) and subsequent processing in a dry zone/module (232).

FIG. 5 is a perspective view of a representative core segment/rail (110) carrying multiple nodules (130).

FIGS. 6A–6C illustrate sectional and underside views of the representative core segment/rail (110) showing internal passages (146) and distribution ports/holes (117).

FIGS. 7A–7D illustrate nodule-wafer interface behavior for the slit opening (142), including an interface view (FIG. 7B), an internal cutaway view (FIG. 7C) illustrating an internal passage (146) associated with the slit region, and a comparative depiction (FIG. 7D) showing the slit opening (142) in an open configuration (middle nodule) and a closed configuration (right-most nodule).

FIG. 8 illustrates a manufacturing/tooling arrangement including a rail fixture/mold body (310), a plurality of mold inserts/pins (330) supported by an upper fixture plate (340), and distribution ports/holes (117).

### DETAILED DESCRIPTION OF THE DRAWINGS

In the following discussion that addresses a number of embodiments and applications of the present invention, reference is made to the accompanying drawings that form a part hereof, and in which is shown by way of illustration specific embodiments in which the invention may be practiced. It is to be understood that other embodiments may be utilized, and changes may be made without departing from the scope of the present invention.

Various inventive features are described below that can each be used independently of one another or in combination with other features. However, any single inventive feature may not address any of the problems discussed above or only address one of the problems discussed above. Further, one or more of the problems discussed above may not be fully addressed by any of the features described below.

As used herein, the singular forms "a", "an" and "the" include plural referents unless the context clearly dictates otherwise. All embodiments of any aspect of the disclosure can be used in combination, unless the context clearly dictates otherwise.

Unless the context clearly requires otherwise, throughout the description and the claims, the words ‘comprise’, ‘comprising’, and the like are to be construed in an inclusive sense as opposed to an exclusive or exhaustive sense; that is to say, in the sense of “including, but not limited to”. Words using the singular or plural number also include the plural and singular number, respectively. Additionally, the words “herein,” “wherein”, “whereas” “above,” and “below” and words of similar import, when used in this application, shall refer to this application as a whole and not to any particular portions of the application.

The description of embodiments of the disclosure is not intended to be exhaustive or to limit the disclosure to the precise form disclosed. While the specific embodiments of, and examples for, the disclosure are described herein for illustrative purposes, various equivalent modifications are possible within the scope of the disclosure, as those skilled in the relevant art will recognize.

In general, the present disclosure relates to wafer-cleaning brushes configured to dispense one or more cleaning fluids through an array of nodules. In use, the cleaning fluid may include deionized (DI) water, a chemical cleaning agent, or a mixture thereof. The brush may be used, for example, in post-chemical mechanical planarization (post-CMP) cleaning and other wet cleaning operations in which controlled delivery of fluid at a brush-wafer interface is desired.

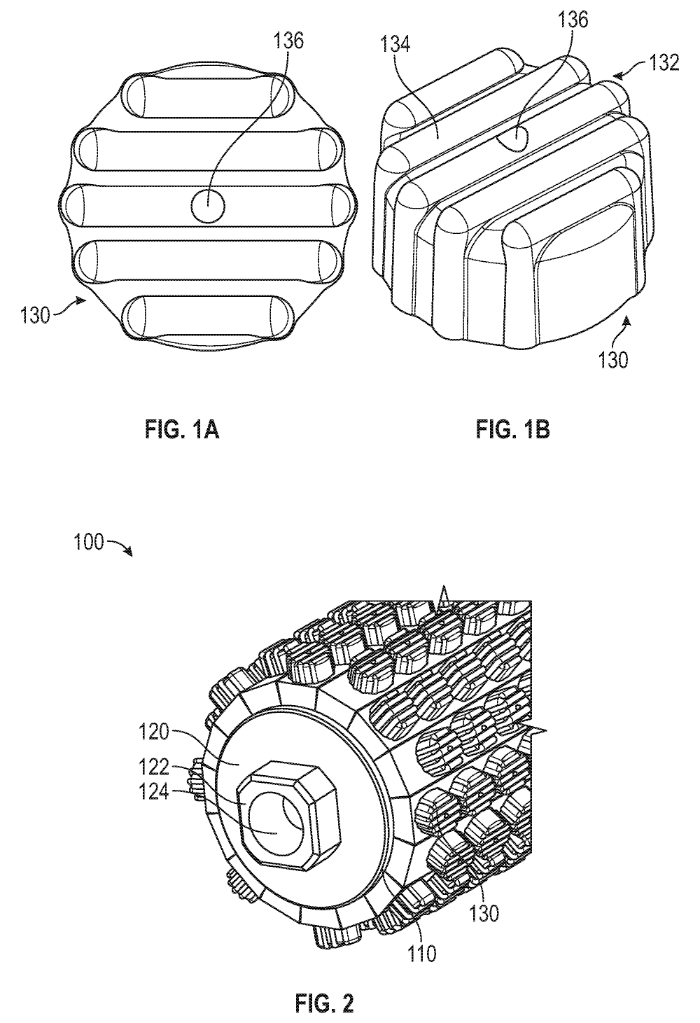

Referring to FIGS. 1A and 1B, a representative nodule 130 is shown. The nodule 130 may be formed of a compliant, fluid-permeable material such as polyvinyl alcohol (PVA), although other fluid-permeable materials may be used. The nodule 130 includes a distal tip 132 configured to contact a wafer surface during cleaning.

In the illustrated embodiment, the distal tip 132 includes surface features 134 such as ridges and/or grooves. The surface features 134 may function as microfluidic guides that direct fluid laterally across the wafer surface, disrupt boundary-layer flow, and reduce pooling or stacking of fluid that may contribute to hydroplaning. The surface features 134 may be arranged in a variety of patterns, including (by way of non-limiting examples) radial, axial, spiral/helical, chevron, and crosshatch patterns, and may be formed integrally with the nodule 130 or by post-processing.

In certain embodiments, the surface features 134 are implemented as ribs that define intervening grooves or channels, and the distal tip 132 includes a peripheral edge region having an edge treatment selected from a chamfer, radius, bevel, or rounded corner. Such ribbed and/or edge-treated geometries can be selected to tune contact mechanics, reduce localized stress at edges, and/or promote lateral spreading of cleaning fluid exiting a dispensing outlet.

In the embodiment of FIGS. 1A and 1B, the nodule 130 further includes a pore or aperture 136 at or near the distal tip 132. During operation, cleaning fluid delivered through the brush may be emitted from the pore 136 at the distal tip 132. The pore 136 may be formed during molding of the nodule 130 or created by post-processing, such as drilling, laser drilling, punching, or other material removal techniques. In some embodiments, the pore 136 may have a characteristic dimension (e.g., diameter) in a range from about 0.1 mm to about 2.0 mm, though other sizes may be used. The pore 136 may be circular, slit-shaped, elliptical, or otherwise shaped, and a given nodule 130 may include one pore 136 or multiple pores 136.

Referring to FIG. 2, a wafer-cleaning brush assembly 100 is shown in a cylindrical embodiment. The brush assembly 100 includes a core 110 that supports a plurality of nodules 130 disposed around an outer surface of the core 110. The core 110 may be hollow and may define an internal chamber (not shown) configured to receive and distribute cleaning fluid. In some embodiments, the core 110 is configured to be driven in rotation about a longitudinal axis during wafer cleaning. The nodules may be arranged on the outer surface of the core in rows or in a helical pattern along the length of the core.

In the illustrated embodiment, an end hub or end cap 120 is coupled to an end of the core 110. The end hub 120 may be a press-fit component and may be sealed to inhibit leakage of cleaning fluid from the end of the core 110 during operation. The end hub 120 may include a drive coupling feature 122 (e.g., a hex interface) configured to interface with a motor-driven coupling. A central bore or opening 124 may be provided, for example, to accommodate a shaft feature or fastening component. In some embodiments, an opposite end (not shown) of the core 110 may include an inlet interface configured to receive cleaning fluid from tool plumbing, and the inlet interface may likewise be sealed against leakage when installed in a processing tool.

Although FIG. 2 shows a cylindrical brush embodiment, the principles described herein are also applicable to brush cores implemented as segments or rails (e.g., as shown in FIGS. 5–8) that may be used as a portion of a cylindrical brush or used in other brush configurations.

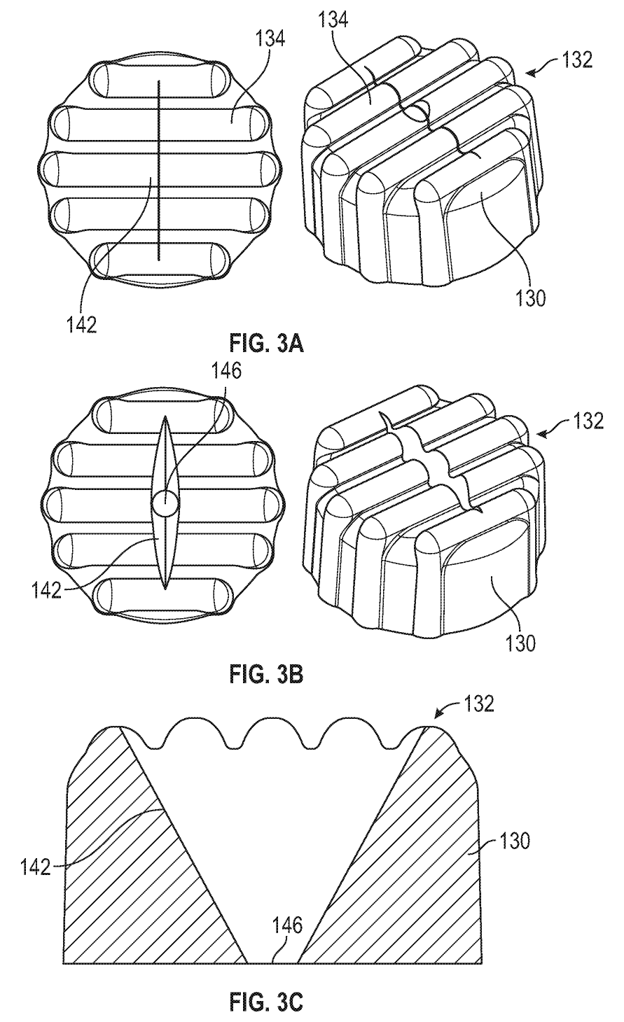

Referring to FIGS. 3A–3C, an embodiment is shown in which the nodule 130 includes a slit opening 142 at or near the distal tip 132. The slit opening 142 may function as a passive dispensing outlet that remains substantially closed in at least one state (e.g., during idle or low-pressure conditions) and opens to dispense cleaning fluid in response to an actuation condition such as internal fluid pressure and/or deformation of the nodule 130 during contact with a wafer.

FIG. 3A illustrates a closed configuration of the slit opening 142. FIG. 3B illustrates an open configuration of the slit opening 142 in which the slit opening 142 separates to create a flow area for dispensing cleaning fluid at the distal tip 132. In the illustrated embodiment, an internal fluid passage or lumen 146 communicates cleaning fluid toward the distal tip 132 and terminates adjacent the slit opening 142, such that the cleaning fluid can be emitted through the slit opening 142 when opened. FIG. 3C illustrates a cross-sectional view of an example slit and lumen arrangement.

The slit opening 142 may be oriented relative to a direction of rotation of the brush assembly 100 and/or relative to the ridge/groove pattern of the surface features 134 to achieve desired wetting and spreading behavior. The geometry of the slit opening 142, as well as properties of the nodule material (e.g., compliance, elasticity, and permeability), may be selected so that the slit opening 142 opens in a controlled manner under operating conditions while tending toward a closed state under reduced pressure and/or reduced contact deformation.

In some embodiments, the slit opening 142 is configured to open upon reaching a pressure threshold within the brush core (e.g., about 1 psi to about 5 psi), and to close when pressure falls below the threshold. In some cases, the slit opening 142 is additionally or alternatively responsive to contact deformation of the nodule 130 during wafer cleaning. In certain embodiments, the slit opening 142 may be implemented as a duckbill-style slit valve, an X-slit valve, or other passive check-valve geometry. Optional valve-enhancement features may include stiffening ribs, anti-reflux features, pre-filters or micro-mesh layers, directional bias features, and/or venturi geometries to tune opening behavior, reduce backflow, and/or reduce particle ingress.

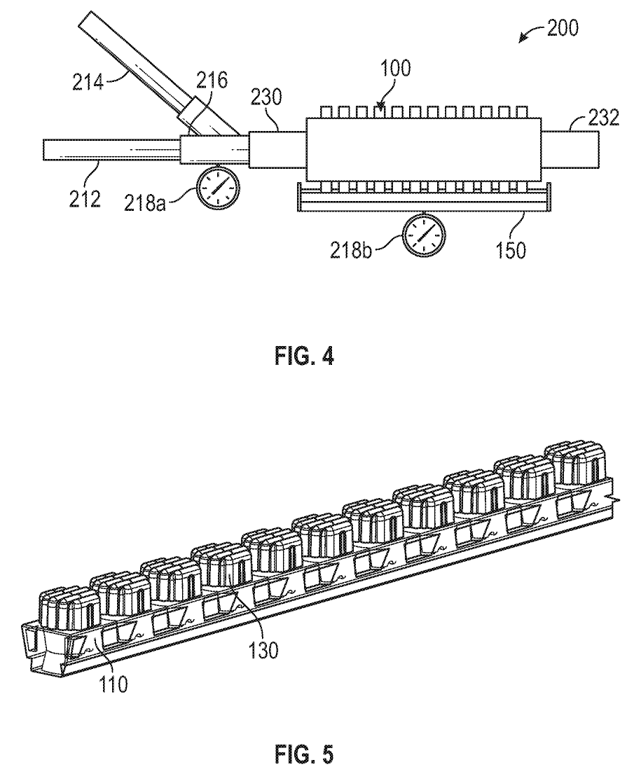

Referring to FIG. 4, a wafer cleaning system 200 is shown. The system 200 may include a DI water supply line or stream 212 and a chemistry supply line or stream 214. The DI water stream 212 and the chemistry stream 214 may be combined at a mixer 216, which may include a Y-fitting or other junction configured to provide a combined cleaning fluid to a wet processing module 230. In some embodiments, one or more dissolved-oxygen (DO) meters 218a and/or 218b may be provided upstream and/or downstream of the mixer 216, for example to monitor DO levels of one or more supplied fluids and/or combined fluids.

In the wet module 230, the brush assembly 100 may apply cleaning fluid to a wafer 150 while performing mechanical cleaning at a brush-wafer interface. In some embodiments, external spray bars are omitted such that cleaning fluid is delivered to the wafer 150 primarily or solely through the brush assembly 100. After wet processing, the wafer 150 may be processed in a dry module 232 (e.g., spin drying), although other downstream processing arrangements may be used.

Referring to FIG. 5, a representative portion of the core 110 is shown as an elongated segment supporting a plurality of nodules 130. The segment of FIG. 5 may represent a portion of a cylindrical brush (e.g., a segment that is assembled into a cylindrical form), or may represent an alternative core geometry in which nodules are supported along an elongated rail.

In some implementations, the segment shown in FIG. 5 is a removable rail module configured to be detachably mounted to a support body or housing of the brush core. The rail module may encapsulate or retain a base portion of the fluid-permeable material and may be replaced as a unit when worn, while the nodules themselves are molded in-place within the rail module and are not individually replaceable.

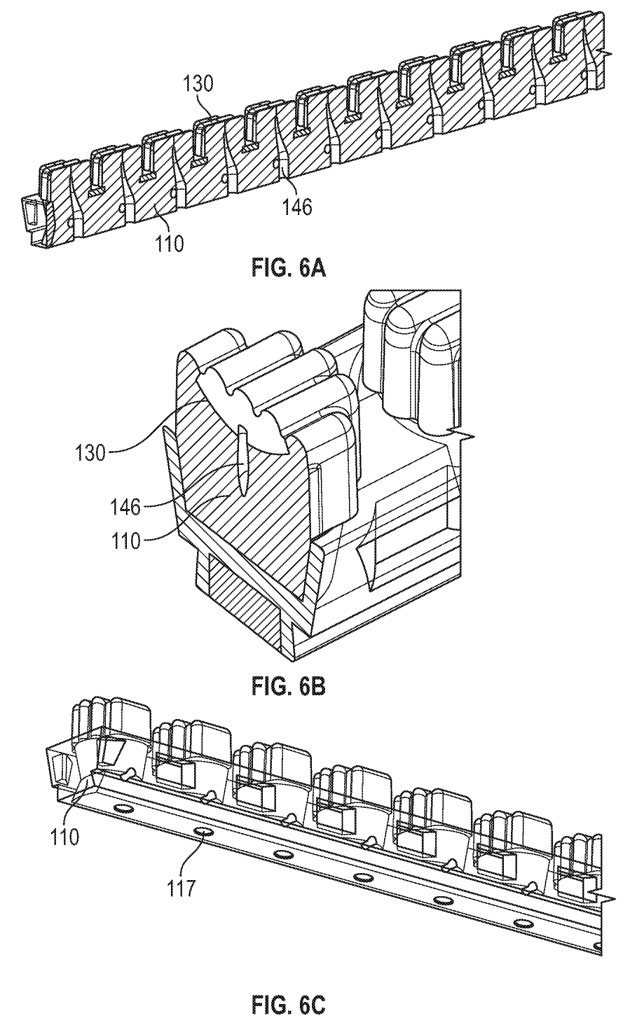

Referring to FIGS. 6A–6C, sectional and underside views of the core 110 segment are shown. In the illustrated embodiment, internal passages 146 are provided within the core 110 and extend toward respective nodules 130. The internal passages 146 may function as risers or conduits that convey cleaning fluid from an internal chamber or manifold region (not shown) toward the nodules 130 and, ultimately, toward dispensing outlets at the distal tips of the nodules 130.

As shown in FIG. 6C, the core 110 may include a plurality of distribution ports or holes 117. The distribution ports 117 may provide communication between tool-side plumbing and internal regions of the core 110, between an internal chamber and the internal passages 146, or between an internal chamber and a fluid-permeable body of the nodules 130. The size, number, spacing, and pattern of the distribution ports 117 may be selected to promote substantially uniform delivery of cleaning fluid along the length of the core 110, including by compensating for pressure drop and flow distribution effects along the brush length.

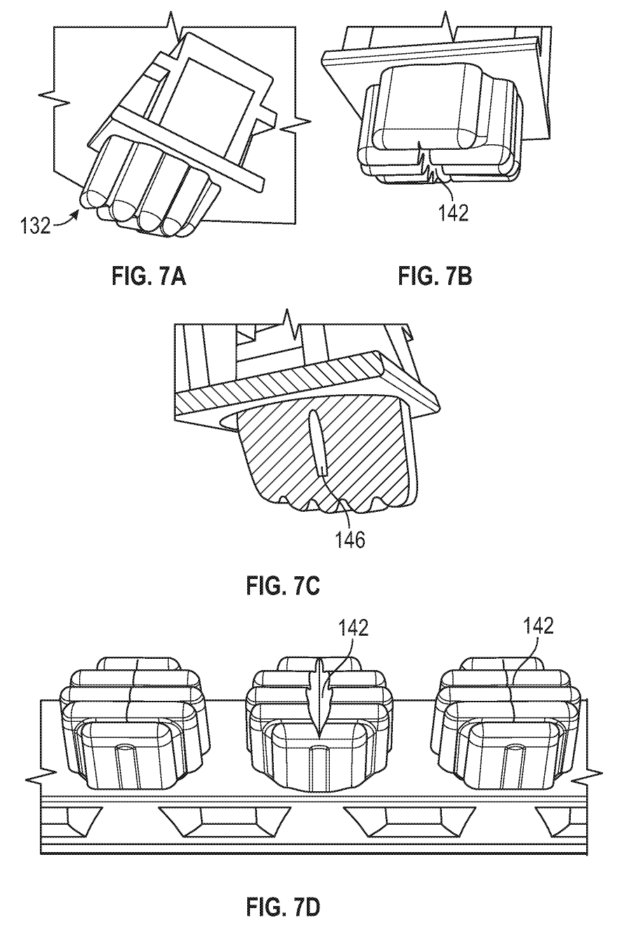

Referring to FIGS. 7A–7D, various views illustrate operation of a slit-based dispensing outlet at a brush-wafer interface. FIG. 7B illustrates an example in which the slit opening 142 is located at a lower region of a nodule where it can dispense cleaning fluid at or near a wafer-contacting region. FIG. 7C illustrates a cutaway cross-sectional view from an interior side of a nodule, showing an internal passage 146 associated with the slit region. FIG. 7D provides a comparative depiction in which the slit opening 142 is illustrated in an open configuration (middle nodule) and in a closed configuration (right-most nodule).

In some examples of the invention, a portion of the fluid pathway (e.g., a portion of the internal passage 146) may act as an open channel that contains a relatively static volume of cleaning fluid during portions of an operating cycle, while a deformable outlet region adjacent the slit opening 142 opens and closes as a result of internal pressure and/or contact-induced deformation of the nodule. In this manner, the brush can dispense cleaning fluid at the interface while tending to reduce dripping and/or uncontrolled flow when the brush is not actively engaged with a wafer.

For example, a first portion of the internal passage 146 may be formed as an open, relatively static channel (e.g., a channel bounded by a more rigid portion of the core or rail) and a second portion near the distal tip may be formed as a deformable outlet region that defines or supports the slit opening 142. In this manner, a volume of cleaning fluid may be retained in the channel while the slit opening 142 remains closed, and dispensed when the deformable outlet region opens under operating conditions.

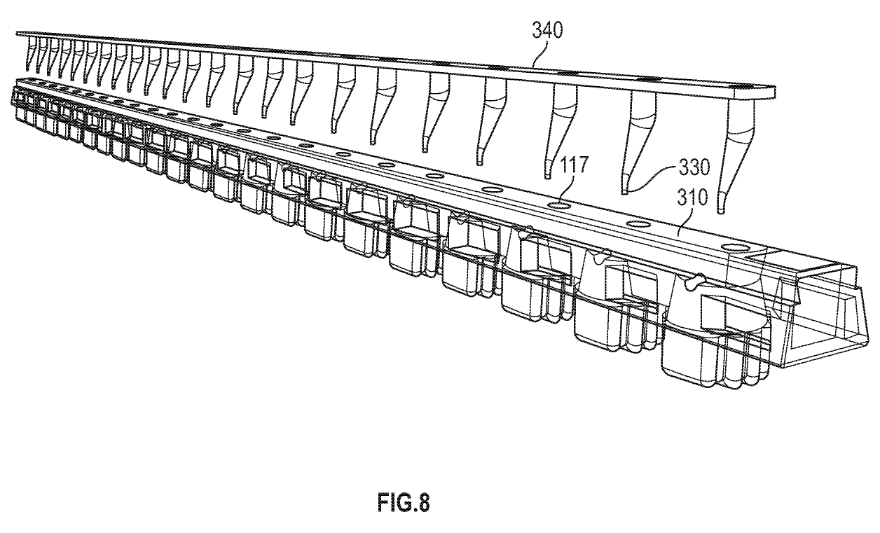

Referring to FIG. 8, an example manufacturing or tooling arrangement is shown. A mold body or rail fixture 310 may define cavity features corresponding to the core 110 segment and/or nodule bases. An upper fixture plate 340 may support a plurality of mold inserts or pins 330. During molding, the inserts 330 may be positioned to form internal passages and/or lumens (e.g., passages corresponding to 146) within molded material. In an example process, a curable resin (e.g., a PVA precursor resin) is introduced into the mold body 310, the inserts 330 are installed, and the resin is cured to form the segment. The inserts 330 may then be removed to leave the internal passages/lumens.

In some embodiments, cavity surfaces of the mold body or rail fixture 310 that define the distal tips of the nodules can be CNC-machined or otherwise precision-formed to provide desired ribbed or edge-treated surface geometries and to promote repeatability of nodule face geometry and porosity-related features.

Following molding, a slit dispensing outlet (e.g., slit opening 142) may be formed by post-processing. For example, a cutting tool (e.g., a spade-shaped knife) may be inserted at a distal tip region of a nodule to create the slit opening. The depth, length, and orientation of the slit opening may be selected to achieve a desired opening behavior under operating conditions. Optionally, distribution ports 117 may be formed by drilling, molding, or other techniques, and may be arranged to provide a desired flow distribution along the core 110.

The foregoing description of embodiments is not intended to be exhaustive. Modifications and variations will be apparent to persons of ordinary skill in the art in view of the present disclosure. The scope of the invention is defined by the appended claims and their equivalents.

### INDUSTRIAL APPLICABILITY

The wafer-cleaning brushes, systems, and methods described herein are industrially applicable to wet processing of substrates, including semiconductor wafer cleaning operations such as post-chemical mechanical planarization (post-CMP) cleaning and other precision surface cleaning processes. The disclosed structures can be implemented in commercial wafer-cleaning tools in which a brush contacts a wafer while one or more process fluids are supplied to a cleaning region.

By providing distributed dispensing of one or more cleaning fluids through an array of nodules at or near the brush-wafer interface, the disclosed embodiments can be used to support controlled placement of deionized water and/or chemical cleaning agents at the contact region, optionally with reduced reliance on external spray delivery hardware. The embodiments are manufacturable using known brush materials and fabrication techniques and can be integrated into existing wet module architectures, including single-sided and double-sided brush cleaning tools, to perform cleaning cycles with controlled delivery of process fluids at the brush-wafer interface.

In certain implementations, the brush assembly and/or removable rail modules are configured as consumable accessory components for existing cleaning tools, with tool-side interfaces (e.g., end caps, couplings, and dimensional constraints) defined by the particular tool configuration. In some cases, multiple end-cap variants and/or rail-module configurations may be provided to match different tool models while maintaining the directed nodule-tip fluid delivery described herein.

The foregoing description has been presented for purposes of illustration and description. It is not intended to be exhaustive or to limit the disclosure to the precise form disclosed. Modifications and variations are possible in light of the above teachings. The scope of the disclosure is defined by the appended claims and their equivalents.

1. A wafer cleaning brush comprising:
a hollow cylindrical core having a proximal end defining a fluid inlet and a distal end that is sealed to define an internal fluid chamber and to promote unidirectional flow of a cleaning fluid along a length of the core;
a plurality of nodules affixed to an outer surface of the core and extending radially outward from the core, each nodule comprising a fluid-permeable material; and
for each of the nodules, a dispensing outlet at a distal tip of the nodule, the dispensing outlet being in fluid communication with the internal fluid chamber, wherein cleaning fluid introduced into the core via the fluid inlet is distributed to the nodules and dispensed from the dispensing outlets at the distal tips during wafer cleaning.

2. The wafer cleaning brush of claim 1, wherein the fluid-permeable material comprises polyvinyl alcohol (PVA).

3. The wafer cleaning brush of claim 1, wherein the nodules are arranged on the outer surface of the core in rows or in a helical pattern along the length of the core.

4. The wafer cleaning brush of claim 1, wherein each dispensing outlet comprises at least one pore or aperture formed at or near the distal tip of the corresponding nodule.

5. The wafer cleaning brush of claim 4, wherein the at least one pore or aperture is circular, slit-shaped, or elliptical.

6. The wafer cleaning brush of claim 4, wherein the at least one pore or aperture has a diameter of about 0.1 mm to about 2.0 mm and is formed during molding of the nodule or by post-processing including laser drilling or punching.

7. The wafer cleaning brush of claim 1, wherein each dispensing outlet comprises a passive valve positioned at or near the distal tip of the corresponding nodule and configured to remain substantially closed in the absence of internal fluid pressure and to open in response to internal fluid pressure to allow the cleaning fluid to exit the nodule.

8. The wafer cleaning brush of claim 7, wherein the passive valve is configured to open upon the internal fluid pressure reaching a defined pressure threshold of about 1 psi to about 5 psi.

9. The wafer cleaning brush of claim 1, wherein the core includes a plurality of distribution ports distributed along the length of the core and configured to deliver the cleaning fluid from the internal fluid chamber into the fluid-permeable material of the nodules, and wherein at least one of a size, a number, or a distribution pattern of the distribution ports is selected to equalize cleaning fluid delivery along the length of the core.

10. The wafer cleaning brush of claim 7, wherein the passive valve comprises a lumen extending within the nodule and a slit at the distal tip; wherein the slit is configured to open in response to at least one of (i) internal fluid pressure and (ii) deformation of the nodule during contact with the wafer; wherein the slit is oriented substantially parallel to a rotational direction of the brush; and wherein the lumen defines an open channel configured to retain a volume of the cleaning fluid when the slit is closed.

11. A wafer cleaning system comprising:
a wafer cleaning brush comprising:
a hollow cylindrical core having a proximal end defining a fluid inlet and a distal end that is sealed to define an internal fluid chamber and to promote unidirectional flow of a cleaning fluid along a length of the core;
a plurality of nodules affixed to an outer surface of the core and extending radially outward from the core, each nodule comprising a fluid-permeable material; and
for each of the nodules, a dispensing outlet at a distal tip of the nodule, the dispensing outlet being in fluid communication with the internal fluid chamber, wherein cleaning fluid introduced into the core via the fluid inlet is distributed to the nodules and dispensed from the dispensing outlets at the distal tips during wafer cleaning;
a fluid supply coupled to the fluid inlet of the core and configured to deliver the cleaning fluid to the internal fluid chamber; and
a drive configured to rotate the wafer cleaning brush during cleaning of a wafer.

12. The wafer cleaning system of claim 11, wherein the cleaning fluid comprises deionized water and at least one chemical cleaning agent.

13. The wafer cleaning system of claim 11, wherein the fluid supply comprises a deionized water supply line and a chemistry supply line fluidically coupled to a Y-fitting configured to combine deionized water and chemistry upstream of the fluid inlet of the core.

14. The wafer cleaning system of claim 13, further comprising a dissolved oxygen meter positioned upstream of the Y-fitting or between the Y-fitting and the fluid inlet of the core.

15. The wafer cleaning system of claim 11, wherein external spray bars are omitted such that cleaning fluid is delivered to the wafer solely through the core and the nodules of the wafer cleaning brush.

16. The wafer cleaning system of claim 11, wherein the core includes a plurality of distribution ports distributed along the length of the core and configured to deliver the cleaning fluid from the internal fluid chamber into the fluid-permeable material of the nodules, and wherein at least one of a size, a number, or a distribution pattern of the distribution ports is selected to equalize cleaning fluid delivery along the length of the core.

17. The wafer cleaning system of claim 11, wherein each dispensing outlet comprises a passive valve positioned at or near the distal tip of the corresponding nodule and configured to remain substantially closed in the absence of internal fluid pressure and to open in response to internal fluid pressure to allow the cleaning fluid to exit the nodule, and the fluid supply is configured to deliver the cleaning fluid at a pressure sufficient to open the passive valves during active cleaning and to reduce dripping during idle states.

18. A method for cleaning a wafer, comprising: introducing a cleaning fluid into a proximal end of a hollow cylindrical core of a wafer cleaning brush, the core having a sealed distal end; rotating the wafer cleaning brush while maintaining contact between distal tips of a plurality of nodules of the wafer cleaning brush and a surface of the wafer; and dispensing the cleaning fluid from dispensing outlets at the distal tips of the nodules onto the surface of the wafer during rotation.

19. The method of claim 18, wherein the dispensing outlets comprise pores or apertures at the distal tips of the nodules.

20. The method of claim 18, wherein the dispensing outlets comprise passive valves that remain substantially closed when internal fluid pressure is below a threshold and open when internal fluid pressure is above the threshold to dispense the cleaning fluid, and wherein the threshold is about 1 psi to about 5 psi.
